(19) United States
(12) Patent Application Publication
(10) Pub. No.: US 2021/0066138 A1
(43) Pub. Date: Mar. 4, 2021

(54) CRYSTALLIZATION MONITORING METHOD, LASER ANNEALING APPARATUS, AND LASER ANNEALING METHOD

(71) Applicant: V TECHNOLOGY CO., LTD., Yokohama-shi, Kanagawa (JP)

(72) Inventors: Michinobu MIZUMURA, Yokohama-shi, Kanagawa (JP); Makoto HATANAKA, Yokohama-shi, Kanagawa (JP); Masami TAKIMOTO, Yokohama-shi, Kanagawa (JP); Kaori SAITO, Yokohama-shi, Kanagawa (JP)

(73) Assignee: V TECHNOLOGY CO., LTD., Yokohama-shi, Kanagawa (JP)

(21) Appl. No.: 16/644,285

(22) PCT Filed: Aug. 24, 2018
(86) PCT No.: PCT/JP2018/031373

§ 371 Date: Mar. 4, 2020

(30) Foreign Application Priority Data
Sep. 6, 2017 (JP) 2017-171138

(51) Int. Cl. H01L 21/66

(52) U.S. Cl. CPC H01L 22/12; H01L 22/26

(57) ABSTRACT

A set of film thickness calculation values of constituent films of a lamination structure is calculated at a set of non-treating regions unexposed to laser light, the non-treating regions residing close to a set of treating regions to be annealed, and a set of crystallization levels of the set of treating regions is calculated by a fitting between a second spectral spectrum measurement values of the set of treating regions and a second spectral spectrum calculation values computed from the set of film thickness calculation values, for use to adjust a set of laser energies of laser light to be irradiated on a TFT substrate to be laser annealed at the next time.

### FIELD OF ART

This invention relates to crystallization monitoring methods that enable grasping electrical characteristics of laser annealed semiconductor thin films, and laser annealing apparatuses and laser annealing methods employing any one of those crystallization monitoring methods.

### BACKGROUND ART

Recent years have observed increased substrate sizes in display devices, such as liquid crystal displays or organic EL displays, requiring performances of thin film transistors (each referred herein to as a TFT) as driving elements to be higher. As TFT channel layers, there has been used polysilicon having high electron mobility, rather than amorphous silicon. For production of such polysilicon, there has been employed a laser annealing method. This laser annealing method is a method of irradiating a beam of laser light to amorphous silicon, having silicon melted by absorbing laser light and rapidly cooled and recrystallized, to thereby change amorphous silicon to polysilicon.

There has been polysilicon produced by such a laser annealing method, having degrees of crystallization greatly influenced by, among others, the quantity of energy of an irradiated laser beam, the thickness of film of amorphous silicon, and the like. There has been polysilicon having varied electric characteristics depending on the degree of crystallization. Accordingly, there has been a need for an observation to be made of a crystallized state of polysilicon as filmed amorphous silicon on a substrate, to know if amorphous silicon is properly recrystallized to polysilicon. Further, it has been desired to obtain a polysilicon film having an even electric characteristic over a surface of a substrate, even if amorphous silicon film in the substrate surface has a distribution of film thickness.

Currently, as methods of observing a state of polysilicon produced by laser annealing, there are three that follow. As a first method there is a so-called macro observation that is a method of visually observing a state of an entirety of a surface of a laser annealed film. As a second method there is a method of performing an observation using an analyzing apparatus such as a scanning electron microscope. As a third method there is a method of measuring an electric characteristic of TFTs, to thereby measure an electron mobility of polysilicon, upon a completion of production of the TFTs.

According to the first method, obtainable results of observation are non-quantitative, so one can only grasp, among others, presence or absence of obvious structural defects, and differences in or unevenness of colors on film surfaces. According to the second method, there are required long times for preparation of samples as objects of observation, and the like. According to the third method, there are many fabrication processes to be implemented to build TFTs after a laser annealing treatment, taking a long time between the laser annealing treatment and a measurement. Such being the case, the second method and the third method cannot confirm any crystal state along with the laser annealing treatment. Therefore, in fabrication processes for display devices, even if there is a defect in electron mobility of polysilicon, there might have been consumed a long time to confirm the defect. Accordingly, until the measurement result is obtained, there might have been produced lots of products (substrates) with defects in electron mobility.

Recent years have observed an evaluation method proposed to confirm a crystal state after a laser annealing treatment without needing a long time until a result of measurement is obtained (refer to a reference listed below as a patent document 1). This evaluation method measures a light transmissivity of a polysilicon film, to perform an evaluation of thin film based on the light transmission. As another method, there is proposed a method of employing spectral characteristics of reflected light from a laser annealed region, to check if an involved laser annealing treatment was properly performed (refer to a reference listed below as a patent document 2).

### LIST OF REFERENCES

### Patent Documents

Patent document 1: JP H10-214869 A
Patent document 2: JP 2016-046330 A

### SUMMARY OF INVENTION

### Problem to be Solved

However, it has been difficult to determine with high accuracy if a laser annealing treatment was properly performed by observing, among others, transmissivity of light transmitted through a polysilicon film, spectral characteristics of light reflected from a surface of the polysilicon film, and the like. For instance, fabrication processes for liquid crystal displays involve forming gate lines on a glass substrate, and sequentially laminating thereon a gate insulation film and an amorphous silicon film. When undergoing a laser annealing treatment, the amorphous silicon film has films residing thereunder. Accordingly, there can be, among others, fluxes of light transmitted through a polysilicon film and fluxes of light reflected from the polysilicon film, and influenced by, among others, films beneath the polysilicon film and involved interfaces. Hence, it has been difficult to determine with high accuracy if the laser annealing treatment was properly performed.

This invention has been devised in view of the foregoing problem, and an object of this invention is to provide a crystallization monitoring method, a laser annealing apparatus, and a laser annealing method that enable a state of crystallization of a semiconductor thin film immediately after a laser annealing treatment to be promptly computed, permitting an electric characteristic of the semiconductor thin film to be grasped, allowing for a defect of the laser annealing treatment to be solved in a short time.

### Solution to Problem

According to aspects of this invention, to solve the problem described, attaining the object, there is provided a crystallization monitoring method including implementing an annealing treatment of irradiating an energy beam set for annealing on a treating region sot of a semiconductor thin film disposed at an uppermost layer of a multi-layered structure formed on a substrate, to crystallize the treating region set, while irradiating illumination light for observation on the semiconductor thin film, measuring reflected light from the semiconductor thin film, thereby observing a crystallization level set of the treating region set, the crystallization monitoring method comprising: calculating a film thickness calculation value set of constituent films of the lamination structure, by a fitting between a first spectral spectrum measurement value set detected by irradiating illumination light for observation on a non-treating region set residing close to the treating region set and unexposed to any energy beam for annealing, measuring outgoing light outgoing from the non-treating region set, and a first spectral spectrum calculation value set computed from a film structure data set of the lamination structure; and calculating a crystallization level set of the treating region set by a fitting between a second spectral spectrum measurement value set detected by irradiating illumination light for observation on the treating region set having an beam set for annealing irradiated thereon, measuring outgoing light outgoing from the treating region set, and a second spectral spectrum calculation value set computed from the film structure data set and the film thickness calculation value set.

According to an aspect, the film structure data set may well comprise data on a film number, materials, design thicknesses, refractive indexes, and absorption coefficients of the constituent films.

According to an aspect, illumination light for observation may well be concurrently irradiated on the treating region set and the non-treating region set, to detect the first dispersed spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively.

According to other aspects of this invention, there is provided a laser annealing apparatus including: a laser annealing treatment implementor including a laser light source set configured to emit laser light for annealing, and an irradiating optical system configured to irradiate laser light emitted from the laser light source set on a treating region set of a semiconductor thin film disposed at an uppermost layer of a lamination structure formed on a substrate; an observation implementor configured to irradiate illumination light for observation on the semiconductor thin film, and measure outgoing light outgoing from the semiconductor thin film, to detect as a spectral spectrum data set; and a control implementor configured to be based on the spectral spectrum data set to control the laser annealing treatment implementor and the observation implementor, wherein the control implementor is configured to: calculate a film thickness calculation value set of constituent films of the lamination structure, by a fitting between a first spectral spectrum measurement value set detected by irradiating illumination light for observation on a non-treating region set residing close to the treating region set and unexposed to any laser light, measuring outgoing light outgoing from the non-treating region set, and a first spectral spectrum calculation value set computed from a film structure data set of the lamination structure; calculate a crystallization level set of the treating region set by a fitting between a second spectral spectrum measurement value set detected by irradiating illumination light for observation on the treating region set having laser light irradiated thereon, measuring outgoing light outgoing from the treating region set, and a second spectral spectrum calculation value set computed from the film structure data set and the film thickness calculation value set; and implement, to the laser annealing treatment implementor, a control set of adjusting a laser energy set of laser light to be irradiated from the laser annealing treatment implementor to a substrate to be laser annealed at a subsequent time, based on the crystallization level set.

According to an aspect, the film structure data set may well comprise data on a film number, materials, design thicknesses, refractive indices, and extinction coefficients of the constituent films.

According to an aspect, the outgoing light may well comprise reflection of illumination light for observation reflected at the semiconductor thin film.

According to an aspect, the observation implementor may well be configured to concurrently irradiate illumination light for observation on the treating region set and the non-treating region set, to detect the first spectral spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively, and the control implementor may well be configured to implement, to the laser annealing treatment implementor, the control set of adjusting the laser energy set of laser light to be irradiated from the laser annealing treatment implementor to a set of treating regions of the substrate correspondent to a set of coordinates of substrate positions of the treating region set to be laser annealed at the subsequent time, in accordance with a set of differences between the crystallization level set and a target crystallization level set.

According to other aspects of this invention, there is provided a laser annealing method comprising: a laser annealing treatment step of irradiating laser light emitted from a laser light source set for annealing on a treating region set of a semiconductor thin film disposed at an uppermost layer of a lamination structure formed on a substrate, to recrystallize the treating region set; a step of irradiating illumination light for observation on the treating region set and a non-treating region set residing close to the treating region set and unexposed to the laser light, measuring outgoing light outgoing from a surface of the substrate, to detect a spectral spectrum data set thereof as detected. a step of calculating a film thickness calculation value set of constituent films of the lamination structure by a fitting between a first spectral spectrum measurement value set obtained at the non-treating region set from among the spectral spectrum data set and a first spectral spectrum calculation value set computed from a film structure data set of the lamination structure; a step of calculating a crystallization level set of the treating region set by a fitting between a second spectral spectrum measurement value set obtained at the treating region set from among the spectral spectrum data set and a second spectral spectrum calculation value set computed from the film structure data set and the film thickness calculation value set; and an adjustment step of implementing, for a substrate to be laser annealed at a subsequent time, an adjustment set of adjusting a laser energy set of laser light to be irradiated in the laser annealing treatment step, based on the crystallization level set.

According to an aspect, the adjustment step may well comprise adjusting the laser energy set of laser light to be irradiated from the laser light source set in accordance with a set of differences between the crystallization level set and a target crystallization level set.

According to an aspect, illumination light for observation may well be concurrently irradiated on the treating region set and the non-treating region set, to detect the first spectral spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively, and the adjustment step may well comprise implementing, for the substrate to be laser annealed at the subsequent time, the adjustment set of adjusting the laser energy set of laser light to be irradiated from the laser light source set to a set of treating regions having a set of coordinates of substrate positions thereof correspondent to the treating region set where the second spectral spectrum measurement value set employed to calculate the crystallization level set is obtained.

### Advantageous Effect

According to aspects of this invention, the crystallization monitoring method, the laser annealing apparatus, and the laser annealing method described each permit a crystallized state set of a semiconductor thin film immediately after a laser annealing treatment (or an annealing treatment) to be promptly computed, allowing for an electric property set of the semiconductor thin film to be grasped. According to aspects of this invention, the laser annealing apparatus and the laser annealing method each permit a defect set after a laser annealing treatment to be solved in a short while, allowing for an enhanced yield as an effect. Further, according to aspects of this invention, there can be obtained a polysilicon film having an even electric characteristic over a surface of a substrate, even if amorphous silicon film in the substrate surface has a distribution of film thickness.

### BRIEF DESCRIPTION OF THE DRAWINGS

FIG. 1 is an explanatory plan view showing a schematic configuration of a TFT substrate to be treated in a laser annealing apparatus according to embodiments of this invention.

FIG. 2 is a partial sectional view at a substrate region of the TFT substrate having a gate line formed therein.

FIG. 3 is a schematic configuration diagram of the laser annealing apparatus according to embodiments of this invention.

FIG. 4 is an explanatory diagram showing the principle of a laser annealing treatment in the laser annealing apparatus according to embodiments of this invention.

FIG. 5 is a hardware configuration diagram of the laser annealing apparatus according to embodiments of this invention.

FIG. 6 is an explanatory diagram showing behaviors depending on a film structure of fluxes of illumination light for observation irradiated on a substrate.

FIG. 7 is a graph showing a set of first reflection spectral spectrum calculation values determined by a fitting to a set of reflection spectral spectrum measurement values measured by using the laser annealing apparatus according to embodiments of this invention.

FIG. 8 is an explanatory diagram showing a simulation model having a laminated structure of an arbitrary number of films.

FIG. 9 is a graph showing sets of reflection spectral spectrum measurement values obtained after laser annealing treatments performed at laser energies using the laser annealing apparatus according to this invention.

FIG. 10 is a graph showing a set of second reflection spectral spectrum calculation values determined by a fitting to a set of reflection spectral spectrum measurement values obtained after a laser annealing treatment performed at a laser energy of 600 mJ/cm².

FIG. 11 is a graph mapping a set of relations between crystallization levels and electron mobilities in polysilicon obtained by laser annealing amorphous silicon.

FIG. 12 is a flowchart showing procedures of a laser annealing method.

FIG. 13 is a table listing a set of relations among film thicknesses of amorphous silicon films, energy densities of irradiated lasers, and crystallization levels (%).

### EMBODIMENTS OF INVENTION

There will be described crystallization monitoring methods, laser annealing apparatuses, and laser annealing methods according to embodiments of this invention into details, with reference to the drawings. However, there are schematic drawings in which respective members have, among others, their dimensions, dimensional ratios, shapes, and the like different from what is real, and among which as well involved parts are different in position of components to be disposed. Further, according to embodiments herein, reflected light from a substrate surface involves outgoing light from a semiconductor thin film on which illumination light for observation is irradiated, and hence, there is employed a reflection spectral spectrum in terms of a spectroscopic spectrum to be measured.

According to embodiments herein, there is a laser annealing apparatus employed for manufacturing, among others, liquid crystal displays and organic EL displays. The laser annealing apparatus is a processing device configured to irradiate laser light as an energy beam set for annealing on an amorphous silicon film as a semiconductor thin film, for melting and recrystallizing the same, to thereby form a polysilicon film set. According to embodiments herein, the laser annealing apparatus is adapted to selectively irradiate laser light on the amorphous silicon film.

The laser annealing apparatus is configured to perform a laser annealing treatment to regions being semiconductor regions each constituting a channel layer of a TFT to be provided for each pixel on a TFT substrate. The TFT substrate is a substrate for, among others, pixel electrodes, TFTs, and the like in an associated liquid crystal to be formed thereon. The TFT substrate constitutes a treating target or a processing target in a crystallization monitoring method, a laser annealing apparatus, or a laser annealing method according to embodiments herein.

(TFT Substrate)

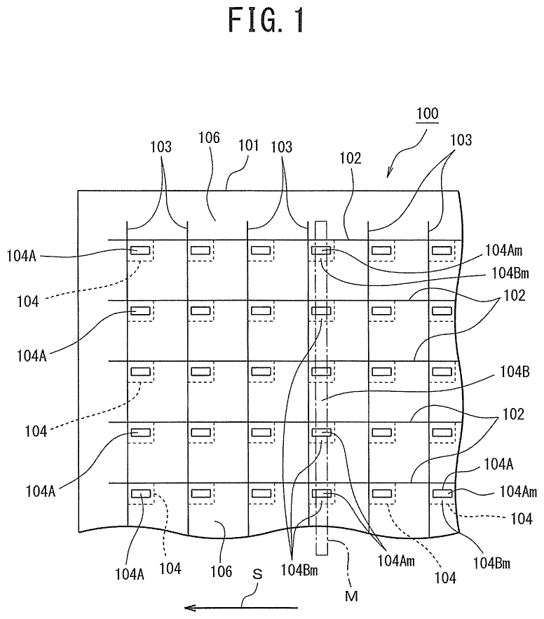

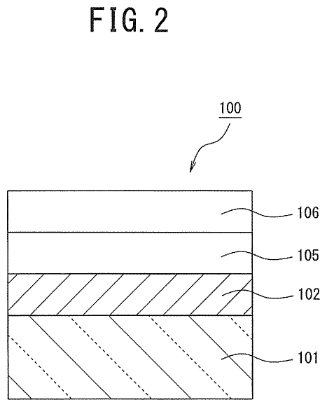

Prior to description of embodiments herein, here is made brief description of a TFT substrate, with reference to FIG. 1 and FIG. 2. FIG. 1 is a plan view of the TFT substrate, and FIG. 2, a partial sectional view at a substrate region thereof having a gate line formed therein.

As shown in FIG. 1, the TFT substrate, designated at 100, has on a glass substrate 101 a combination of gate lines 102 (with gate electrode pattern portions inclusive) and data lines 103 formed thereon, crossing each other in a matrix array. There is a set of TFT forming regions 104 each respectively provided near an intersection between an associated gate line 102 and an associated data line 103, for a corresponding TFT to be formed therein as a switching element (as a driving element). It is noted that, according to embodiments herein, the TFT substrate 100 to be processed in the laser annealing apparatus is put in a previous state thereof for, among others, the data lines 103, a non-depicted combination of source electrodes and drain electrodes, and the like to be formed thereon, and has an amorphous silicon film 106 as an upper most layer.

The laser annealing treatment to be performed to such the TFT substrate 100 is to be performed to the amorphous silicon film 106 that is an uppermost layer of a laminated structure. As shown in FIG. 1, the glass substrate 101 is to have gate lines 102 formed thereon to extend in parallel to each other. As shown in FIG. 2, the glass substrate 101 having gate lines 102 formed thereon is to have a gate insulating film 105 formed thereon, to have the amorphous silicon film 106 formed thereon.

As shown in FIG. 1, on the surface of the amorphous silicon film 106, there is provided a set of matrixed treating regions 104A designed to form therein a matrix of semiconductor regions each constituting a channel layer at a corresponding TFT forming region 104. To each row of such treating regions 104A, an annealing treatment is performed by having an array of beams of laser light selectively irradiated thereon.

(Laser Annealing Apparatus)

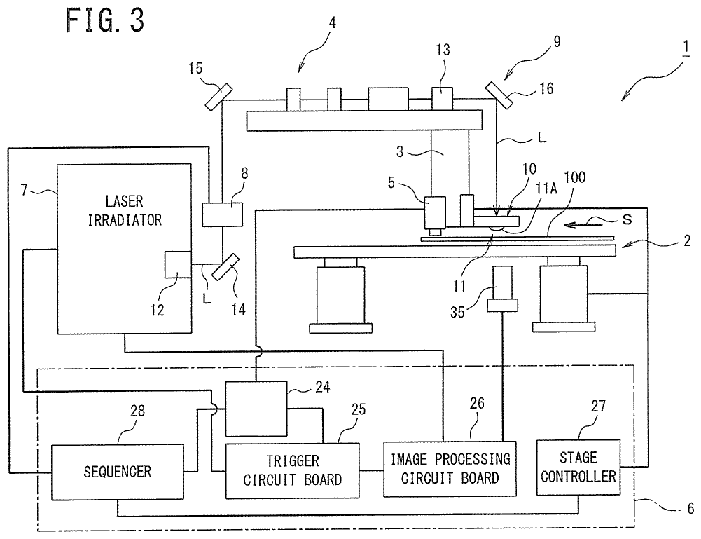

Description is now made of configuration of the laser annealing apparatus according to embodiments herein. As shown in FIG. 3, according to embodiments of this invention, the laser annealing apparatus, designated at 1, includes a substrate stage 2, a micro-lens array stage 3, a laser annealing treatment implementor 4, a crystallization monitoring implementor 5 as an observation implementor, and a control implementor 6.

(Substrate Stage)

As shown in FIG. 3, the substrate stage 2 includes a non-depicted transport device configured to carry the TFT substrate 100, to move at a prescribed pitch along a scan direction S (indicated by an arrow). Under the substrate stage 2, there is disposed a substrate position observing camera 35 for performing a positional detection of the TFT substrate 100.

It is noted that the TFT substrate 100 to be processed in embodiments herein has the amorphous silicon film 106 as an uppermost layer, and stands as a substrate in a state before formation of, among others, the data lines 103 (see FIG. 1), the non-depicted combination of source electrodes and drain electrodes, and the like. Further, as shown in FIG. 1, according to embodiments herein, the scan direction S of the TFT substrate 100 is set to be orthogonal to the data lines 103.

(Laser Annealing Treatment Implementor)

The laser annealing treatment implementor 4 includes a laser irradiator 7, an attenuator 8, an irradiating optical system 9, a mask 10, and a micro-lens array 11. The laser annealing treatment implementor 4 is provided to the micro-lens array stage 3 fixed in position above the substrate stage 2.

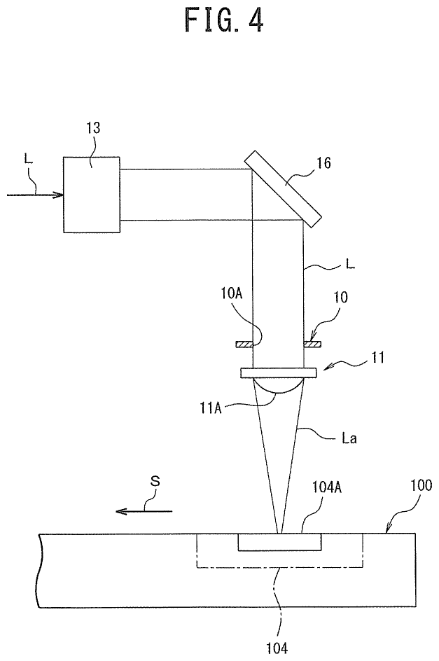

According to embodiments herein, the laser annealing treatment implementor 4 is configured to irradiate an array of laser beams La (see FIG. 4) arrayed in a direction perpendicular to the scan direction S, to the TFT substrate 100 disposed in position on the substrate stage 2. It is noted that the array of laser beams La has an identical pitch to a pitch of rows of treating regions 104A disposed to array in a direction perpendicular to the scan direction S of the TFT substrate 100. It also is noted that the pitch between laser beams La may well be set to a pitch equal to an integer multiple of two or more of the pitch between rows of treating regions 104A arrayed in a direction perpendicular to the scan direction S of the TFT substrate 100. Further, it is noted that the number of beams of laser light L to be finally irradiated on the TFT substrate 100, as well as the pitch between such beams of laser light L, can be set in dependence on a combination of variable configurations, such as those of a set of laser light sources 12, the irradiating optical system 9, the mask 10, and the micro-lens array 11.

In the laser irradiator 7 shown in FIG. 3, the set of laser light sources 12 includes laser light sources 12 to be enough in number to finally obtain the array of laser beams La. The laser light sources 12 are each respectively configured to irradiate a beam of laser light L with a preset pulse frequency. The attenuator 8 has a function of attenuating, to adjust, beams of laser light L outgoing from the set of laser light sources 12, as necessary. The irradiating optical system 9 includes, among others, a set of beam homogenizers 13, sets of mirrors 14, 15, and 16, and the like.

Here is made brief description of the mask 10 and the micro-lens array 11. The mask 10 as well as the micro-lens array 11 is provided at the micro-lens array stage 3. The mask 10 has an array of apertures 10A formed therein to array along a direction perpendicular to the scan direction S of the TFT substrate 100, the apertures 10A opening to the substrate stage 2.

The micro-lens array 11 is configured as an array of micro-lenses 11A each respectively disposed in position to face a corresponding aperture 10A in the array of apertures 10A in the mask 10. In other words, the micro-lens array 11 as well as the mask 10 is configured to be elongate, and disposed to extend, along a direction perpendicular to the scan direction S of the TFT substrate 100 at the substrate stage 2. It is noted that, in FIG. 4, although there is depicted along the scan direction S a combination of a single column of apertures 10A and a single column of micro-lenses 11A, there actually is a combination of a plurality of columns of apertures 10A and a plurality of columns of micro-lenses 11A each arrayed along the scan direction S, as well known. Namely, in the mask 10, there is formed a set of apertures 10A arrayed in a two-dimensional matrix. In correspondence thereto, in the micro-lens array 11 also, there is provided a set of micro-lenses 11A arrayed in a two-dimensional matrix.

As shown in FIG. 4, in the micro-lens array 11, the micro-lenses 11A are each respectively configured to be set up for condensing fluxes of laser light La to concentrate or focus on a treating region 104A in a corresponding TFT forming region 104 of the TFT substrate 100. There can be a set of beams of laser light La condensed by the micro-lens array 11 and selectively irradiated on a set of treating regions 104A arrayed in a matrix on the TFT substrate 100. According to embodiments herein, such the configuration can avoid unnecessarily crystallize those regions requiring no laser annealing treatments.

The laser annealing treatment implementor 4 is thus adapted for irradiating laser beams La over the array of treating regions 104A, to thereby implement laser annealing treatments of the set of TFT forming regions 104 on the TFT substrate 100. Specifically, for the laser annealing treatments to be column-wise sequentially performed, the TFT substrate 100 on the substrate stage 2 may well be translated by a pitch of columns of treating regions 104A arrayed along the scan direction S at the TFT substrate 100.

(Crystallization Monitoring Implementor)

Description is now made of configuration of the crystallization monitoring implementor 5. As shown in FIG. 3, the crystallization monitoring implementor 5 is provided at the micro-lens array stage 3.

The crystallization monitoring implementor 5 is configured to enable a monitoring of an area on the TFT substrate 100 including: a column of treating regions 104A to be irradiated with beams of laser light La; and a column of non-treating regions 104B (as a column of amorphous silicon film regions) each respectively close to an adjacent treating region 104A, but not exposed to any beam of laser light La.

FIG. 1 has dash-dot lines drawn in parallel to a direction perpendicular to the scan direction S, to define a region in between as a monitoring region M to be observed by the crystallization monitoring implementor 5. The monitoring region M is defined as an elongate region along a direction perpendicular to the scan direction S of the TFT substrate 100. At the monitoring region M, there is made a set of measurements of reflected light Lm.

Specifically, there are made measurements covering sets of fluxes of reflected light Lm reflected from a set of first measuring points 104Bm disposed in non-treating regions 104B and a set of second measuring points 104Am disposed in treating regions 104A. The first measuring points 104Bm disposed in the non-treating regions 104B are each respectively located to be vicinal to a corresponding treating region 104A (i.e., vicinal thereto in a vertical direction in the figure that is a direction perpendicular to the scan direction S). The second measuring points 104Am are each respectively located at an inside of a corresponding one of treating regions 104A irradiated with beams of laser light La.

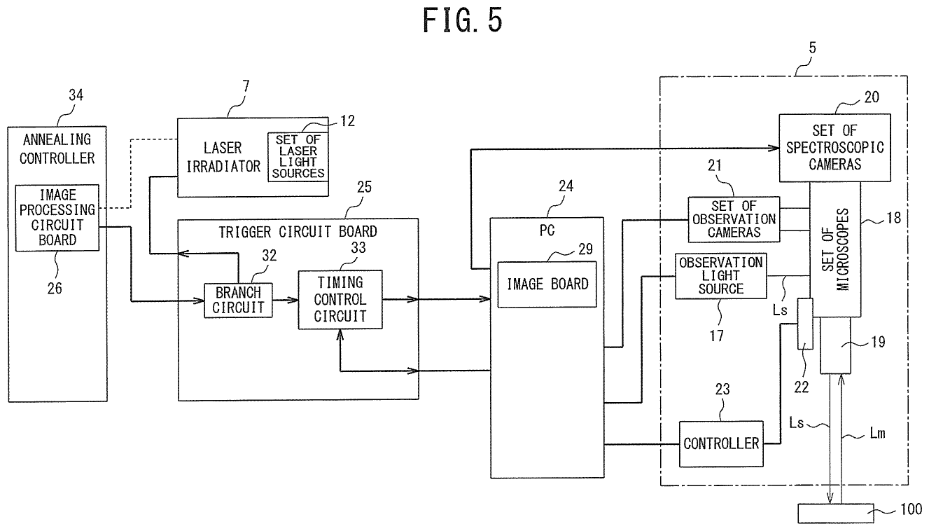

As shown in FIG. 5, the crystallization monitoring implementor 5 includes an observation light source 17, a set of microscopes 18, a set of objective lenses 19, a set of spectroscopic cameras 20, a set of observation cameras 21, a set of Z-axis direction drives 22, and a controller 23.

The observation light source 17 is a light source for emitting fluxes of visible illumination light Ls to be irradiated over a surface area of the monitoring region M, for observation thereof. There can be a set of fluxes of illumination light Ls for observation consisting of subsets thereof each respectively introduced into a tube of an associated microscope 18, conducted along an optical axis to pass through an associated objective lens 19, and irradiated onto an involved surface area (as a combination of a treating region 104A and a non-treating region 104B) on the TFT substrate 100. It is noted that the subsets of the set of fluxes of illumination light Ls for observation to be irradiated on involved surface areas of the TFT substrate 100 are designed to provide a line lighting along the monitoring region M. Accordingly, there can be a set of fluxes of reflected light Lm consisting of subsets thereof each respectively reflected from an involved surface area of the TFT substrate 100, conducted through an associated objective lens 19 to enter an associated microscope 18, and measured at an associated spectroscopic camera 20.

It is noted that the subsets of the set of fluxes of reflected light Lm from involved surface areas of the TFT substrate 100 constitute a linear array of fluxes of reflected light, like the subsets of the set of fluxes of illumination light Ls for observation. The spectroscopic cameras 20 are arranged in a linear camera array to enable measurements to be made of, from among such the linearly arrayed subsets of the set of fluxes of reflected light Lm, each subset involving those fluxes of light Lm reflected from a second measuring point 104Am in a corresponding treating region 104A and from a first measuring point 104Bm in a non-treating region 104B residing close to the treating region 104A. The set of spectroscopic cameras 20 is configured to implement a set of spectroscopic measurements of reflection Lm, to thereby detect a set of spectral spectra of reflection in the form of a set of two-dimensional planar data. The set of observation cameras 21 is configured to acquire a set of two-dimensional planar data on spectral spectra of reflection detected by the set of spectroscopic cameras 20, and output the same to the control implementor 6 side.

(Control Implementor)

Description is now made of schematic configuration of the control implementor 6, with reference to FIG. 3. According to embodiments herein, the control implementor 6 includes a personal computer (referred herein to as a PC) 24 working as an arithmetic unit, a trigger circuit board 25, an image processing circuit board 26, a stage controller 27, and a sequencer 28. It is noted that according to embodiments herein the PC 24 in use is not limited thereto, and may well be substituted by another arithmetic unit.

As shown in FIG. 5, the PC 24 has an image board 29 incorporated therein. The PC 24 is connected to the observation light source 17, the set of spectroscopic cameras 20, the set of observation cameras 21, the controller 23, the trigger circuit board 25, and the sequencer 28 (see FIG. 3).

The sequencer 28 has stored therein a combination of a film thickness computing program for computing film thicknesses of constituent films at the non-treating regions 104B and a crystallization level computing program for computing crystallization levels at the treating regions 104A. It is noted that, for each film having amorphous silicon and polysilicon mixed therein, there is defined a term “crystallization level (A)” as a content ratio (%) of polysilicon. It also is noted that, according to embodiments herein, the configuration having the film thickness computing program and the crystallization level computing program stored in the sequencer 28 may well be modified to a configuration having them stored in the PC 24.

As shown in FIG. 5, the trigger circuit board 25 includes a branch circuit 32 and a timing control circuit 33. As shown in FIG. 3, the trigger circuit board 25 is connected to the laser irradiator 7, the PC 24, the image processing circuit board 26, and the sequencer 28.

Further, as shown in FIG. 5, the image processing circuit board 26 is incorporated in an annealing controller 34. As shown in FIG. 3, the image processing circuit board 26 is connected to the substrate position observing camera 35, the laser irradiator 7, and the trigger circuit board 25. The image processing circuit board 26 is operable to acquire a set of pieces of information on a position of the TFT substrate 100, from the substrate position observing camera 35. The image processing circuit board 26 works to output a sequence of shot trigger signals to the trigger circuit board 25.

As will be seen from FIG. 5, at the trigger circuit board 25, the branch circuit 32 works to receive a shot trigger signal output from the image processing circuit board 26, to output to the laser irradiator 7. The laser irradiator 7 is operable in response to the shot trigger signal, to drive the set of laser light sources 12, to output beams of laser light L with prescribed irradiation laser energies.

At the trigger circuit board 25, the timing control circuit 33 has a trigger shot signal input thereto from the image processing circuit board 26 via the branch circuit 32, whereby the timing control circuit 33 is operated to output a trigger signal to the image board 29 in the PC.

With the trigger signal input to the image board 29, the PC 24 is operated to output drive signals to the observation light source 17, the set of spectroscopic cameras 20, the set of observation cameras 21, the controller 23, and the like. The controller 23 is configured to drive and control the set of Z-axis direction drives 22. The PC 24 is operated to import from the set of observation cameras 21, a set of two-dimensional planar data of reflection spectra, as it is obtained by the set of spectroscopic cameras 20, at the timing the trigger signal is output.

The stage controller 27 is connected to the sequencer 28, and a non-depicted transport device in the substrate stage 2. The stage controller 27 is configured to implement a control for driving the non-depicted transport device, to move the TFT substrate 100 in the scan direction S.

The film thickness computing program is programmed to: receive a set of film structure data to be input to the sequencer 28, including data on the number of films, materials, and a combination of designed film thicknesses, refractive indices, and extinction coefficients of constituent films of an involved lamination structure; and calculate a set of first reflection spectral spectrum calculation values to be derived by estimation from the set of film structure data. Further, the film thickness computing program is programmed to make a fitting between a set of first reflection spectral spectrum measurement values obtained at a set of first measuring points 104Bm in an involved array of non-treating regions 104B, as it is input from the set of observation cameras 21 to the image board 29, and a set of first reflection spectral spectrum calculation values for the set of first measuring points 104Bm, to thereby calculate a set of film thickness calculation values for constituent films of the set of first measuring points 104Bm residing element-wise close to a prescribed array of treating regions 104A.

The crystallization level computing program is programmed to calculate a set of second reflection spectral spectrum calculation values from the set of film structure data combined with the set of film thickness calculation values calculated for the above-noted constituent films by the film thickness computing program. Further, the crystallization level computing program is programmed to make a fitting between a set of second reflection spectral spectrum measurement values obtained from (a set of second measuring points 104Am in) the array of treating regions 104A, as it is input from the set of observation cameras 21 to the image board 29, and the set of second reflection spectral spectrum calculation values, to thereby calculate a set of crystallization levels (A) for the array of treating regions 104A. It is noted that the film thickness computing program as well as the crystallization level computing program has a sequence of computing procedures written therein as software, as it is employed in the following crystallization monitoring method.

(Crystallization Monitoring Method)

Description is now made of a crystallization monitoring method applied to the laser annealing apparatus 1, prior to operations of a laser annealing apparatus to be described later.

According to embodiments herein, the crystallization monitoring method includes melting and recrystallizing an array of treating regions 104A of an amorphous silicon film 106, followed by, irradiating fluxes of illumination light Ls for observation on a combination of the array of treating regions 104A and an array of non-treating regions 104B element-wise close to the array of treating regions 104A, measuring reflected light Lm therefrom with the set of spectroscopic cameras 20, obtaining a set of reflection spectral spectrum measurement values in a two-dimensional plane.

The crystallization monitoring method is programmed to calculate a set of first reflection spectral spectrum calculation values (as a first spectral spectrum calculation value set) by using a set of pieces of information as data on a film structure (including the number of films, materials, and a combination of designed film thicknesses, refractive indices, and extinction coefficients of constituent films of an involved multi-layered structure) of the TFT substrate 100. Further, it is programmed to make a fitting between the set of first reflection spectral spectrum calculation values and a set of first reflection spectral spectrum measurement values (as a first spectral spectrum measurement value set) that is a set of measured values to be taken at an array of non-treating regions 104B element-wise close to a specific array of treating regions 104A, from among the set of reflection spectral spectrum measurement values detected as a two-dimensional planar data set, to thereby calculate a set of film thickness calculation values for the array of non-treating regions 104B.

It is still programmed to make a fitting between “a set of second reflection spectral spectrum measurement values (as a second spectral spectrum measurement value set) taken, from among the set of reflection spectral spectrum measurement values detected in the form of a two-dimensional planar data set, as a subset thereof involving measurement values of reflection reflected from the array of treating regions 104A that is irradiated with a combination of beams of laser light L and fluxes of illumination light Ls for observation”, and “a set of second reflection spectral spectrum calculation values (as a second spectral spectrum calculation value set) to be calculated from a combination of the set of data on the film structure and the set of film thickness calculation values derived therefrom”, to thereby calculate a set of crystallization levels (A) for the array of treating regions 104A.

The term “crystallization level (A)” means a content ratio (%) of polysilicon in a film having amorphous silicon and polysilicon mixed therein, as described. At each TFT 104, the crystallization level (A) is proportional to the electron mobility representing an electric performance. At each treating region 104A as laser annealed, grasping the crystallization level (A) enables a laser annealed state thereof to be numerically grasped.

According to embodiments herein, the laser annealing apparatus 1 is an apparatus employing such the crystallization monitoring method, and is well adapted to calculate a set of crystallization levels (A) in real time immediately after a laser annealing treatment. Accordingly, the laser annealing apparatus 1 can implement a feedback control in accordance with a set of calculated crystallization levels (A).

Hence, according to the laser annealing apparatus 1, for a TFT substrate 100 to be laser annealed next time, there can be implemented a laser annealing treatment to emit thereto laser light L from the laser annealing treatment implementor 4, with laser energies adjusted based on a set of crystallization levels (A) after the previous laser annealing treatment. For laser energy adjustments, there may well be a combination of adjustments in laser irradiation density, pulse number, etc.

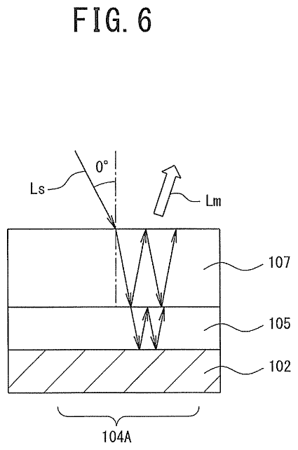

There will be described the crystallization monitoring method, into details. The crystallization monitoring method includes using the crystallization monitoring implementor 5 for measuring fluxes of reflected light Lm from an array of non-treating regions 104B element-wise close to an array of treating regions 104A of an amorphous silicon film 106, to obtain a set of first reflection spectral spectrum measurement values. Further, the crystallization monitoring method includes using the crystallization monitoring implementor 5 for measuring fluxes of reflected light Lm from polysilicon films 107 (see FIG. 6) in the array of treating regions 104A, to obtain a set of second reflection spectral spectrum measurement values. Then, there is detected a set of reflection spectral spectrum measurement values in the form of a two-dimensional planar data set involving, among others, a combination of the set of first reflection spectral spectrum measurement values and the set of second reflection spectral spectrum measurement values, as it is measured.

FIG. 6 shows a lamination structure composed of a gate line (as a gate electrode) 102, a gate insulation film 105, and a polysilicon film 107 formed in this order on the glass substrate 101 (see FIG. 1). FIG. 6 illustrates a set of fluxes of illumination light Ls for observation incident to a surface of the polysilicon film 107, and a set of fluxes of reflection Lm thereof The set of fluxes of illumination light Ls for observation is incident at an angle preset to be normal to the surface of the polysilicon film 107.

The set of fluxes of illumination light Ls for observation incident to the polysilicon film 107 is preset to have subsets thereof reflected as boundary surface reflections, such as those at the surface of the polysilicon film 107, at an interface between the polysilicon film 107 and the gate insulation film 105, and at an interface between the gate insulation film 105 and the gate line 102, involving (outgoing) fluxes of light constituting the set of fluxes of reflection Lm to be incident to the crystallization monitoring implementor 5. For the method under discussion, the crystallization monitoring implementor 5 is configured to have the set of fluxes of reflection Lm incident thereto and measured by the set of spectroscopic cameras 20, to obtain the set of reflection spectral spectrum measurement values in the form of a two-dimensional planar data set, as described.

As illustrated in FIG. 6, the set of fluxes of illumination light Ls for observation has subsets thereof reflected by the gate line (as a gate electrode) 102, which is made of a high reflective material, e.g., titanium nitride (TiN) having a high reflectivity, or the like, so the set of fluxes of reflection Lm being a reflection thereof has a unique reflection property depending mainly on a multi-layered structure involving the gate insulation film 105 and the polysilicon film 107.

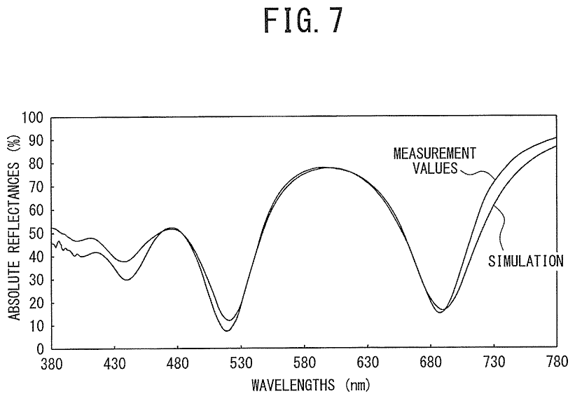

FIG. 7 shows a waveform of a simulation after a fitting made over a fitting wavelength range between 430 nm and 700 nm, for instance, to a set of reflection spectral spectrum measurement values obtained from the polysilicon film 107 as recrystallized after a laser annealing treatment.

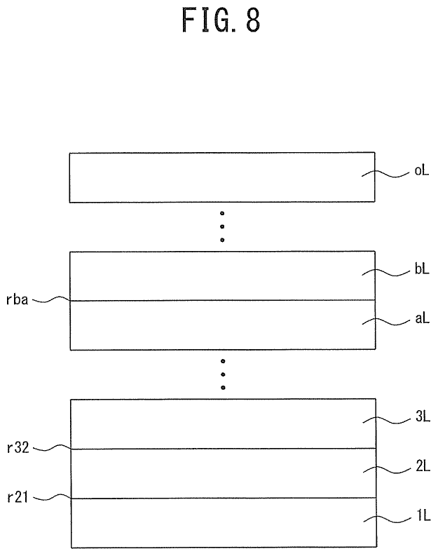

FIG. 8 is an illustration of the structure of lamination as a model for the simulation. In the illustration, the lamination structure has material layers thereof sequentially stacked [symbol] laminated as constituent films 1L, 2L, 3L, . . . , aL, bL, . . . , and oL in the order from the lowest layer. As shown in FIG. 8, there is assumed a vertical lamination of constituent films involving a sequence of pairings of mutually contacting films having reflectivities r21, r32, and rba at their interfaces, respectively.

For the lamination of constituent films oL through 1L, both inclusive, there is a set of combinations of their refractive indices, extinction coefficients, and film thicknesses defined such that:

constituent film oL (refractive index,extinction coefficient,film thickness)=(no,ko,do),

constituent film bL (refractive index,extinction coefficient,film thickness)=(nb,kb,db),

constituent film aL (refractive index,extinction coefficient,film thickness)=(na,ka,da),

constituent film 3L (refractive index,extinction coefficient,film thickness)=(n3,k3,d3),

constituent film 2L (refractive index,extinction coefficient,film thickness)=(n2,k2,d2), and

constituent film 1L (refractive index,extinction coefficient,film thickness)=(n1,k1,d1).

For the constituent films bL through 1L, both inclusive, there is a set of their complex refractive indices defined such that:

complex refractive index Nb of constituent film bL=nb−kb*i,

complex refractive index Na of constituent film aL=na−ka*i,

complex refractive index N3 of constituent film 3L=n3−k3*i,

complex refractive index N2 of constituent film 2L=n2−k2*i, and

complex refractive index N1 of constituent film 1L=n1−k1*i,

where i is an imaginary unit.

Then, for each constituent film, there is computed a combination of φ calculations to be each respectively made for a corresponding one of measuring wavelengths λ. For the constituent film aL, for instance, there is employed an expression for associated φ calculations, such that:

φa=2π*Na*da/λ(λ: wavelength).

For a respective one of measuring wavelengths λ, there is computed a combination of r (repetitive reflection) calculations to be each respectively made for a corresponding one of involved interfaces. For a calculation for an r to be determined, there is employed an expression such that:

rba=(Nb−Na)/(Nb+Na).

For calculations for r's of layers to be sequentially determined from a lower layer, there is employed a combination of expressions such that:

r(cba)={rcb+rba*exp(−2i*φb)}/{1+rcb*rba*exp(−2i*φb)}, and

r(dcba)={rdc+rcba*exp(−2i*φc)}/{1+rdc*rcba*exp(−2i*φc)}.

Then, for r's of layers of whole constituent films, there is computed a set of intensity calculations. For calculation of a simulation reflectance Rsim, there is employed an expression such that:

Rsim=r*r*.

The foregoing calculation method is applicable to have a set of combinations of film thickness calculation values computed by setting data on a film configuration (as the number of films, materials, and designed film thicknesses), and combinations of refractive indices n and extinction coefficients k for constituent films.

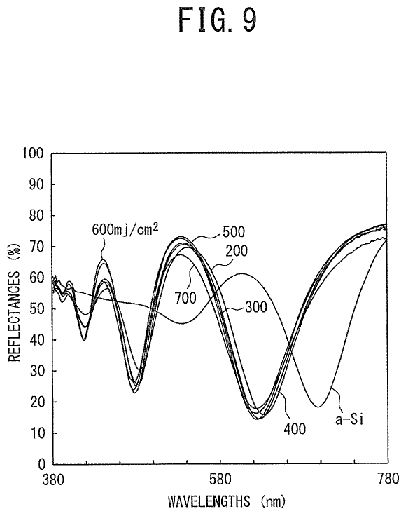

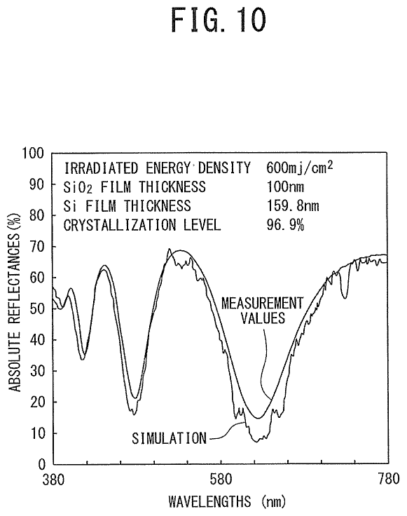

FIG. 9 shows a combination of sets of reflection spectral spectrum data of polysilicon films 107 after laser annealing treatments implemented with varied energy densities irradiated as laser energies. Employed lasers were KrF excimer lasers. FIG. 10 shows an example of simulation involving a fitting to a set of reflection spectral spectrum measurement values (as a set of second reflection spectral spectrum measurement values) after a laser annealing treatment implemented with an irradiation laser energy density of 600 mJ/cm², for instance, as it was taken from among the sets of reflection spectral spectrum data shown in FIG. 9. This fitting was a fitting between the set of reflection spectral spectrum measurement values taken after the irradiation with a laser energy density of 600 mJ/cm², and a set of reflection spectral spectrum calculation values (as a set of second reflection spectral spectrum calculation values) computed from a combination of a set of data on a film structure and a set of film thickness calculation values, as they had been obtained by calculations described for constituent films in an associated array of non-treating regions 104B (that is, at a set of first measuring points 104Bm). By the fitting, there could be a set of uniquely calculated crystallization levels (A).

For the set of crystallization levels (A) to be determined, methods of calculation employed were as following. For measured values of reflection spectra (as integrated spectra), the following calculations were made for a respective one of measuring wavelengths λ. It is noted that, for expression of a crystallization level (A) at a respective polysilicon film as an uppermost layer, there was employed a combination of parameters involving

for a-Si:
a refractive index na,
an extinction coefficient ka, and
a complex refractive index Na=na−ka*i, and

for single crystal silicon:
a refractive index nc,
an extinction coefficient kc, and
a complex refractive index Nc=nc−kc*i.

For calculation of a complex permittivity for amorphous silicon and for single crystal silicon, there were employed the following expressions:

εa=Na2, and

εc=Nc2.

For calculation of a complex permittivity c for polysilicon of an involved constituent film, there was employed a combination of equations such that:

ε2+(−1.5*X*εa+1.5*X*εb−εb+0.5*εa)*εa*εb/2=0 and

0=fa(εa−ε)/(εa+2ε)+fb(εh−ε)/(εh+2ε),

of which ε was calculated from the solution formula.

For the constituent film, the complex permittivity c was employed to calculate a complex refractive index NSi such that:

NSi=ε0.5.

Like calculations made in the fitting of film thicknesses, there was computed a set of refractive indices. Then, as a set of film thicknesses of constituent films, there was assigned the set of film thickness calculation values obtained as a result of the film thickness fitting described.

As a result of such the fitting, there was obtained the set of reflection spectral spectrum calculation values (as a set of second reflection spectral spectrum calculation values) shown in FIG. 10. For a combination of a refractive index n poly-Si and an extinction coefficient k poly-Si of polysilicon film 107, there was employed a combination of an expression (1) and an expression (2) as following.

n poly-Si=na-Si×A+nc-Si×(1−A) (1), and

k poly-Si=ka-Si×A+kc-Si×(1−A) (2),

where na-Si is a refractive index of amorphous silicon,

nc-Si is a refractive index of single crystal silicon,

ka-Si is an extinction coefficient of amorphous silicon,

kc-Si is an extinction coefficient of single crystal silicon, and

A is a crystallization level expressed in terms of a ratio of a-Si/poly-Si.

Accordingly, from the expressions (1) and (2), there can be calculated a value of the crystallization level (A) in the expressions.

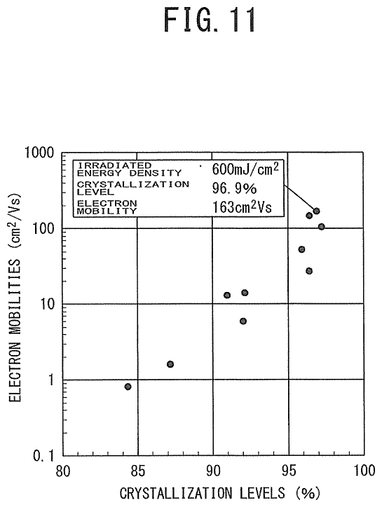

As a result of the fitting shown in FIG. 10, there was calculated a crystallization level (A) of polysilicon film 107 to be 96.9%, for instance, in the case of a laser annealing treatment implemented with an energy density of 600 mJ/cm². FIG. 11 shows a set of relations between such crystallization levels (A) and electron mobilities in polysilicon obtained by laser annealing amorphous silicon. In FIG. 11, for the crystallization level (A) of 96.9% obtained by the calculation described, there is found a corresponding electron mobility of 163 cm²/Vs. Such being the case, determining a crystallization level (A) permits a numerical grasp of an electron mobility in polysilicon after an involved laser annealing treatment.

There has been described a crystallization monitoring method. There may well be an identical or similar method employed to determine a set of crystallization levels in the laser annealing apparatus 1 and a laser annealing method according to embodiments herein. Further, according to embodiments herein, the laser annealing apparatus 1 as well as the laser annealing method may well employ data on values of crystallization levels (A), as a basis to implement (a) control(s) of a laser energy or laser energies, such as (an) adjustment(s) of energy density or energy densities of (a) laser beam(s) to be irradiated.

(Operations of Laser Annealing Apparatus)

Description is now made of operations of the laser annealing apparatus 1. First, according to embodiments herein, the laser annealing apparatus 1 has a TFT substrate 100 disposed on the substrate stage 2, and exposed to a laser annealing treatment implemented with a set of prescribed irradiation laser energy densities by the laser annealing treatment implementor 4. At this time, there is a set of beams of laser light La selectively irradiated on a set of treating regions 104A arrayed in a direction perpendicular to the scan direction S of the TFT substrate 100. By the laser annealing treatment, the TFT substrate 100 has amorphous silicon constituting an uppermost layer in a lamination structure thereof selectively recrystallized to polysilicon.

Concurrently with the laser annealing treatment, the crystallization monitoring implementor 5 is driven for operating the set of spectroscopic cameras 20 to measure reflection Lm from a combination of first measuring points 104Bm and second measuring points 104Am pixel-wise disposed to array in a direction perpendicular to the scan direction S of the TFT substrate 100. There is a set of spectral spectra of reflection caught by the set of spectroscopic cameras 20, and detected as a set of two-dimensional planar data by the set of observation cameras 21. The set of two-dimensional planar data detected by the set of observation cameras 21 is taken into the image board 29 in the PC 24.

The set of two-dimensional planar data on spectral spectra of reflection is taken in from the PC 24 to the sequencer 28, where it is processed by combination of the film thickness computing program and the crystallization level computing program, to have a set of crystallization levels (A) computed for an array of treating regions 104A element-wise disposed at locations on a set of coordinates of substrate positions.

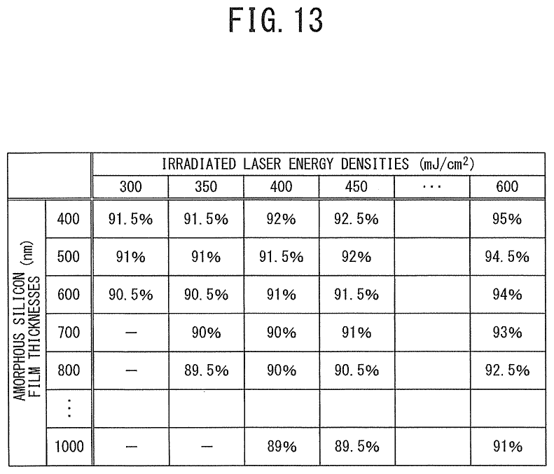

According to embodiments herein, at the laser annealing apparatus 1, the sequencer 28 has a table prepared as illustrated in FIG. 13, to list a set of target crystallization levels to be element-wise compared with a set of computed crystallization levels (A), for collation of the latter with the table to implement (a) control(s) of changing an energy or energies of (a) laser beam(s) for use in the next treatment of the TFT substrate 100.

For instance, assuming a location having a combination of a film thickness of 600 nm obtained by the film thickness computing program, a crystallization level (A) computed to be 90.5% by the crystallization level computing program, and a target crystallization level of 94%, there would be a change caused on a recipe of the sequencer 28, by collation with the table, to change the energy density of a laser beam to be irradiated at the location to 600 mJ/cm². Such the change or changes in irradiation laser energy density is/are to be reflected to realize in the next laser annealing treatment of the TFT substrate 100.

(Laser Annealing Method)

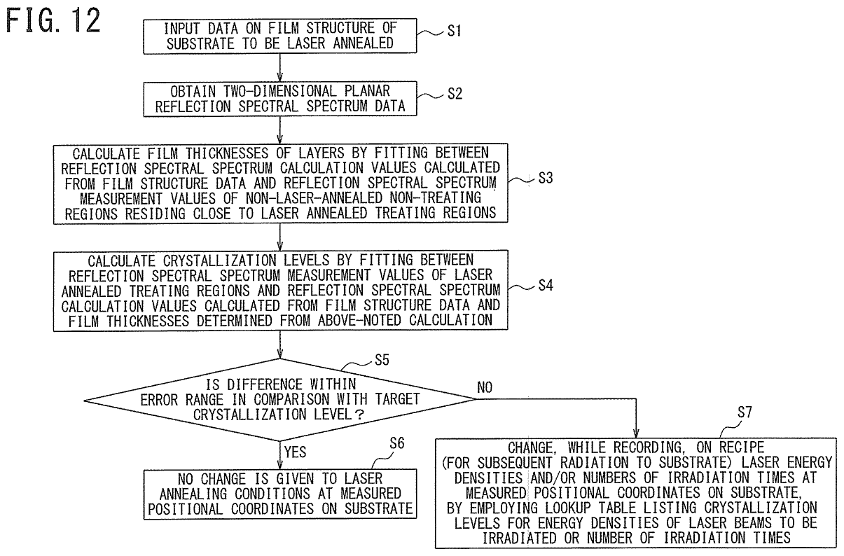

FIG. 12 is a flowchart showing essential steps of a laser annealing method according to embodiments herein. There will be described the laser annealing method. According to embodiments herein, the laser annealing method to be described is applied to the laser annealing apparatus 1.

First, at a step S1, there is input a set of data on a film structure of a TFT substrate 100 to be laser annealed in the laser annealing method.

Next, at a step S2, there is implemented a laser annealing treatment to an array of treating regions 104A on the TFT substrate 100, and concurrently therewith, there is obtained a set of spectral spectrum data on reflection from all of first measuring points 104Bm and second measuring points 104Am residing within an involved monitoring region M, as shown in FIG. 1.

Next, at a step S3, there is calculated a set of film thicknesses of associated constituent films by a fitting between a set of first reflection spectral spectrum calculation values calculated from the set of film structure data, and a set of first reflection spectral spectrum measurement values of (an array of first measuring points 104Bm in) non-laser-annealed non-treating regions 104B residing close to laser-annealed treating regions 104A, as it is taken from among the set of reflection spectral spectrum data obtained above. The set of film structure data is a data set including data on a film number, materials, and design film thicknesses of an involved lamination structure, and a combination of a refractivity and an extinction coefficient of each constituent film.

Next, at a step S4, there is calculated a set of crystallization levels calculated by a fitting between a set of second reflection spectral spectrum calculation values of an array of second measuring points 104Am located in the laser-annealed treating regions 104A, and a set of second reflection spectral spectrum calculation values calculated from the set of film structure data and the set of film thicknesses of constituent films calculated at the step S3.

Next, at a step S5, the set of crystallization levels obtained at the step S4 is element-wise compared with a set of target crystallization levels to obtain a set of differences between above-obtained crystallization levels and target crystallization levels, to determine whether or not the set of differences element-wise resides within a set of error ranges.

If the set of differences between crystallization levels and target crystallization levels, as it is obtained at the step S5, element-wise resides within the set of error ranges, the flow goes to a step S6 to have no change given to a set of laser annealing conditions at an involved array of coordinates of substrate positions of which the crystallization level set is calculated.

On the other hand, if the set of differences between crystallization levels and target crystallization levels, as it is obtained at the step S5, is element-wise equal to or greater than the set of error ranges, the flow goes to a step S7 to implement a processing for adjustment as following. Namely, if the set of differences between crystallization levels and target crystallization levels, as it is obtained at the step S5, involves any subset thereof element-wise equal to or greater than a corresponding subset of the set of error ranges, then at the step S7, the sequencer 28 is operated to element-wise change, as necessary, while recording, on a recipe thereof, a set of combinations of energy density and/or numbers of irradiation times for beams of laser light to be irradiated at a set of coordinates of substrate positions where measurements are made, in accordance with a lookup table listing crystallization levels for combinations of energy densities of laser beams to be irradiated and numbers of pulsing times. Such recorded energy densities of laser beams to be irradiated and/or numbers of irradiation times are to be reflected on a subsequent laser annealing treatment.

According to embodiments herein, the laser annealing method is programmed to concurrently irradiate an array of non-treating regions 104B and an array of treating regions 104A with fluxes of illumination light Ls for observation, and detect a set of first reflection spectral spectrum measurement values and a set of second reflection spectral spectrum measurement values, as sets of two-dimensional planar data to be correspondent to sets of coordinates of substrate positions of the array of non-treating regions 104B and the array of treating regions 104A where the set of first reflection spectral spectrum measurement values and the set of second reflection spectral spectrum measurement values are measured, respectively.

Then, at the step S7 being a processing for adjustment, laser energies are adjusted for an array of treating regions 104A residing at the same sets of coordinates on a TFT substrate 100 to be laser annealed next time, as sets of coordinates of substrate positions of the array of treating regions 104A for which the set of crystallization levels described is determined in a previous treatment. It is noted that as a method of adjusting energy densities of laser beams irradiated, there may well be added controlling the attenuator 8 by the sequencer 28.

(Advantageous Effects of Laser Annealing Apparatus)

According to embodiments herein, the laser annealing apparatus 1 is adapted to instantly compute a state of crystallization of polysilicon crystallized promptly after a laser annealing treatment to amorphous silicon. Grasping the crystallization level permits an electric property of prepared polysilicon to be grasped. Accordingly, there can be prevented occurrences of defects after a subsequent laser annealing treatment. Therefore, according to embodiments herein, the laser annealing apparatus 1 allows for a wide enhanced yield in a fabrication process of a TFT substrate 100.

Further, according to embodiments herein, the laser annealing apparatus 1 is configured to detect a set of first reflection spectral spectrum measurement values and a set of second reflection spectral spectrum measurement values, as sets of two-dimensional planar data to be correspondent to sets of coordinates of substrate positions of an involved array of non-treating regions 104B and an involved array of treating regions 104A where the set of first reflection spectral spectrum measurement values and the set of second reflection spectral spectrum measurement values are measured, respectively.

Therefore, when laser annealing TFT substrates in a lot, assuming the TFT substrates to have an identical film structure, it is possible to make electron mobilities of an array of treating regions 104A even within a substrate surface of a TFT substrate 100 to be treated next time. Namely, even in a case involving a distribution developed in a film structure within a substrate surface along with an upsizing of screen, it is possible to make uniform electron mobilities of TFT substrates 100 in a lot. Accordingly, there is an effect allowing for an enhanced display performance of a liquid crystal display including a TFT substrate 100 fabricated by the laser annealing apparatus 1.

### OTHER EMBODIMENTS

Although there have been described crystallization monitoring methods, laser annealing apparatuses, and laser annealing methods according to embodiments of this invention, drawings and discussions constituting part of disclosure of those embodiments should not be construed as limiting the invention. From this disclosure, various alternative embodiments, examples and operational techniques will be apparent to those skilled in the art.

For instance, although in the embodiments described there has been employed a configuration to concurrently implement a laser annealing treatment to a set of treating regions 104A arrayed in a direction perpendicular to a scan direction S of a TFT substrate 100, there may well be employed a configuration to intermittently implement laser annealing treatments at a pitch equal to an integer multiple of twice or more a pitch of an array of treating regions 104A along a direction perpendicular to the scan direction S of the TFT substrate 100.

In the embodiments described there has been employed a configuration to measure fluxes of reflected light Lm from all of treating regions 104A in a set of treating regions 104A arrayed in a direction perpendicular to the scan direction S of the TFT substrate 100 and non-treating regions 104B in a set of non-treating regions 104B residing in vicinities of the treating regions 104A. However, according to embodiments of this invention, there may well be employed a configuration not to measure fluxes of reflected light Lm from all treating regions 104A or non-treating regions 104B in vicinities thereof, but to measure fluxes of reflect light Lm simply from essential points.

Although in embodiments herein there is a crystallization monitoring method applied to the laser annealing apparatus 1 and the laser annealing method described, the crystallization monitoring method may well be applied to other annealing apparatuses or annealing methods, such as a lamp annealing, for instance, that do not employ any laser beam set as an energy beam set for annealing, as a matter of course.

Although in embodiments described there has been application of an amorphous silicon film to prepare a polysilicon film as a semiconductor thin film, applicable material films are not limited thereto.

Although in embodiments described the laser annealing apparatus 1 has is set up to concurrently drive the laser annealing treatment implementor 4 and the crystallization monitoring implementor 5, to concurrently perform irradiation of laser light La and irradiation of illumination light Ls for observation, there may well be a setting to have illumination light Ls irradiated for observation at a later timing than irradiation of laser light La.

Although in embodiments described the laser annealing apparatus 1 is configured to measure reflection Lm as fluxes of outgoing light outgoing from semiconductor thin films, there may well be employed a configuration for irradiating a substrate stage 2 from below with fluxes of illumination light Ls for observation, to measure fluxes of transmitted light transmitted through a TFT substrate 100 by using the crystallization monitoring implementor 5. For instance, in situations involving an amorphous silicon film formed on a glass substrate, to prepare TFTs in the form of a top gate structure (of a staggered type), there may well be employed a configuration for irradiating the glass substrate from below with a set of fluxes of illumination light for observation, to measure a transmitted subset thereof by using the crystallization monitoring implementor 5.

Although in embodiments described the laser annealing apparatus 1 is configured to have a set of apertures 10A of a mask 10 disposed to array in a single column in a direction perpendicular to a scan direction S of a TFT substrate 100, there may well be employed a configuration to have them arrayed in a plurality of columns. Further, in accordance therewith, the micro-lens array 11 also may well have micro lenses 11A thereof arrayed in a plurality of columns.

According to embodiments herein, the laser annealing apparatus 1 may well be configured for computing a set of crystallization levels (A), to compare with a set of target crystallization levels, to thereby determine a set of laser energy values to be set up for a subsequent irradiation, or to implement such a degree of control as adjusting a combination of increments and decrements, without determining laser energy values to be set up, for a subsequent irradiation.

### DESCRIPTION OF SIGNS

L, La laser light (as an energy beam set for annealing)
Ls illumination light for observation
Lm reflection (as outgoing light)
M monitoring region
1 laser annealing apparatus
2 substrate stage
4 laser annealing treatment implementor
5 crystallization monitoring implementor (as an observation implementor)
6 control implementor
7 laser irradiator
12 laser light source
17 light source for observation
20 spectroscopic camera
21 observation camera
23 controller
24 PC
25 trigger circuit board
26 image processing circuit board
27 stage controller
28 sequencer
29 image board
100 TFT substrate
104 TFT forming region
104A treating region
104Am second measuring point
104B non-treating region
104Bm first measuring point
105 gate insulating film
106 amorphous silicon film (as a semiconductor thin film)
107 polysilicon film

1. A crystallization monitoring method including implementing an annealing treatment of irradiating an energy beam set for annealing on a treating region set of a semiconductor thin film disposed at an uppermost layer of a lamination structure formed on a substrate, to crystallize the treating region set, while irradiating illumination light for observation on the semiconductor thin film, measuring outgoing light outgoing from the semiconductor thin film, thereby observing a crystallization level set of the treating region set, the crystallization monitoring method comprising:
calculating a film thickness calculation value set of constituent films of the lamination structure, by a fitting between a first spectral spectrum measurement value set detected by irradiating illumination light for observation on a non-treating region set residing close to the treating region set and unexposed to any energy beam for annealing, measuring outgoing light outgoing from the non-treating region set, and a first spectral spectrum calculation value set computed from a film structure data set of the lamination structure; and
calculating a crystallization level set of the treating region set by a fitting between a second spectral spectrum measurement value set detected by irradiating illumination light for observation on the treating region set having an beam set for annealing irradiated thereon, measuring outgoing light outgoing from the treating region set, and a second spectral spectrum calculation value set computed from the film structure data set and the film thickness calculation value set.

2. The crystallization monitoring method as claimed in claim 1, wherein the film structure data set comprises data on a film number, materials, design thicknesses, refractive indices, and extinction coefficients of the constituent films.

3. The crystallization monitoring method as claimed in claim 1, wherein illumination light for observation is concurrently irradiated on the treating region set and the non-treating region set, to detect the first spectral spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively.

4. A laser annealing apparatus including:
a laser annealing treatment implementor including a laser light source set configured to emit laser light for annealing, and an irradiating optical system configured to irradiate laser light emitted from the laser light source set on a treating region set of a semiconductor thin film disposed at an uppermost layer of a lamination structure formed on a substrate;
an observation implementor configured to irradiate illumination light for observation on the semiconductor thin film, and measure outgoing light outgoing from the semiconductor thin film, to detect as a spectral spectrum data set; and
a control implementor configured to be based on the spectral spectrum data set to control the laser annealing treatment implementor and the observation implementor, wherein the control implementor is configured to:
calculate a film thickness calculation value set of constituent films of the lamination structure, by a fitting between a first spectral spectrum measurement value set detected by irradiating illumination light for observation on a non-treating region set residing close to the treating region set and unexposed to any laser light, measuring outgoing light outgoing from the non-treating region set, and a first spectral spectrum calculation value set computed from a film structure data set of the lamination structure;
calculate a crystallization level set of the treating region set by a fitting between a second spectral spectrum measurement value set detected by irradiating illumination light for observation on the treating region set having laser light irradiated thereon, measuring outgoing light outgoing from the treating region set, and a second spectral spectrum calculation value set computed from the film structure data set and the film thickness calculation value set; and
implement, to the laser annealing treatment implementor, a control set of adjusting a laser energy set of laser light to be irradiated from the laser annealing treatment implementor to a substrate to be laser annealed at a subsequent time, based on the crystallization level set.

5. The laser annealing apparatus as claimed in claim 4, wherein the film structure data set comprises data on a film number, materials, design thicknesses, refractive indices, and extinction coefficients of the constituent films.

6. The laser annealing apparatus as claimed in claim 4, wherein the outgoing light comprises reflection of illumination light for observation reflected at the semiconductor thin film.

7. The laser annealing apparatus as claimed in claim 4, wherein
the observation implementor is configured to concurrently irradiate illumination light for observation on the treating region set and the non-treating region set, to detect the first spectral spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively, and
the control implementor is configured to implement, to the laser annealing treatment implementor, the control set of adjusting the laser energy set of laser light to be irradiated from the laser annealing treatment implementor to a set of treating regions of the substrate correspondent to a set of coordinates of substrate positions of the treating region set to be laser annealed at the subsequent time, in accordance with a set of differences between the crystallization level set and a target crystallization level set.

8. A laser annealing method comprising:
a laser annealing treatment step of irradiating laser light emitted from a laser light source set for annealing on a treating region set of a semiconductor thin film disposed at an uppermost layer of a lamination structure formed on a substrate, to recrystallize the treating region set;
a step of irradiating illumination light for observation on the treating region set and a non-treating region set residing close to the treating region set and unexposed to the laser light, measuring outgoing light outgoing from a surface of the substrate, to detect a spectral spectrum data set thereof as detected,
a step of calculating a film thickness calculation value set of constituent films of the lamination structure by a fitting between a first spectral spectrum measurement value set obtained at the non-treating region set from among the spectral spectrum data set and a first spectral spectrum calculation value set computed from a film structure data set of the lamination structure;
a step of calculating a crystallization level set of the treating region set by a fitting between a second spectral spectrum measurement value set obtained at the treating region set from among the spectral spectrum data set and a second spectral spectrum calculation value set computed from the film structure data set and the film thickness calculation value set; and
an adjustment step of implementing, for a substrate to be laser annealed at a subsequent time, an adjustment set of adjusting a laser energy set of laser light to be irradiated in the laser annealing treatment step, based on the crystallization level set.

9. The laser annealing method as claimed in claim 8, wherein the adjustment step comprises adjusting the laser energy set of laser light to be irradiated from the laser light source set in accordance with a set of differences between the crystallization level set and a target crystallization level set.

10. The laser annealing method as claimed in claim 8, wherein
illumination light for observation is concurrently irradiated on the treating region set and the non-treating region set, to detect the first spectral spectrum measurement value set and the second spectral spectrum measurement value set as sets of two-dimensional planar data to be correspondent to sets of coordinates of substrate positions of the non-treating region set and the treating region set where the first spectral spectrum measurement value set and the second spectral spectrum measurement value set are measured, respectively, and
the adjustment step comprises implementing, for the substrate to be laser annealed at the subsequent time, the adjustment set of adjusting the laser energy set of laser light to be irradiated from the laser light source set to a set of treating regions having a set of coordinates of substrate positions thereof correspondent to the treating region set where the second spectral spectrum measurement value set employed to calculate the crystallization level set is obtained.
